(19) United States
(12) Patent Application Publication
(10) Pub. No.: US 2011/0308845 A1
(43) Pub. Date: Dec. 22, 2011

(54) PRINTED CIRCUIT BOARD AND METHOD OF MANUFACTURING THE SAME

(75) Inventors: Suk Hyeon CHO, Gyeonggi-do (KR); Jung Hyun Park, Gyeonggi-do (KR)

(73) Assignee: Samsung Electro-Mechanics Co., Ltd., Suwon (KR)

(21) Appl. No.: 13/164,055

(22) Filed: Jun. 20, 2011

(30) Foreign Application Priority Data
Jun. 21, 2010 (KR) 10-2010-0058611

(51) Int. Cl. H05K 1/09; H05K 3/42; H05K 1/11

(52) U.S. Cl. 174/257; 174/266; 29/852

(57) ABSTRACT

The present invention provides a printed circuit board including: an insulating member having a through via hole; a circuit pattern disposed on the insulating member; a solder resist disposed on the insulating member while exposing a portion of the circuit pattern; a via plating pad connected to the circuit pattern, disposed inside the via hole, and covering a lower opening of the via hole along an inner wall of the via hole; and an external connection means having a center portion coinciding with a center portion of the via hole and disposed on the via plating pad, and a method of manufacturing the same.

### CROSS-REFERENCE TO RELATED APPLICATIONS

Claim and incorporate by reference domestic priority application and foreign priority application as follows:

### “CROSS REFERENCE TO RELATED APPLICATION

This application claims the benefit under 35 U.S.C. Section 119 of Korean Patent Application Serial No. 10-2010-0058611, entitled filed Jun. 21, 2010, which is hereby incorporated by reference in its entirety into this application.”

### BACKGROUND OF THE INVENTION

1. Field of the Invention

The present invention relates to a printed circuit board and a method of manufacturing the same, and more particularly, to a printed circuit board including an external connection means disposed inside a via hole, having a center portion coinciding with a center portion of a lower opening of the via hole, and disposed on a via plating pad, and a method of manufacturing the same.

2. Description of the Related Art

A printed circuit board may include an insulating layer, a circuit pattern disposed on at least one surface of the insulating layer, a via passing through the insulating layer to perform interlayer connection, and so on. Here, the circuit pattern may include a pad for connection to a chip or an external circuit portion. At this time, in case of a ball grid array (BGA) type printed circuit board, it is possible to connect a pad and a chip or a pad and an external circuit portion by using a solder ball.

Recently, as packages get smaller and highly functionalized, the number of chips mounted inside a printed circuit board is greatly increased. Therefore, it is required to mount many solder balls in a limited area of the printed circuit board. However, since a via and a pad should be disposed in different regions of the printed circuit board, there was a limit on increasing a solder ball mounting region inside the printed circuit board.

Meanwhile, as price competition for electronic products has been increased, many attempts to reduce process costs of a printed circuit board, a key component of the electronic product, have been made. Raw material costs or indirect costs may be reduced to reduce the process costs of the printed circuit board, but it caused deterioration of quality of the product.

Therefore, there is a need for a printed circuit board capable of reducing process costs as well as saving a circuit space.

### SUMMARY OF THE INVENTION

The present invention has been invented in order to overcome the above-described problems and it is, therefore, an object of the present invention to provide a printed circuit board including an external connection means disposed inside a via hole, having a center portion coinciding with a center portion of a lower opening of the via hole, and disposed on a via plating pad, and a method of manufacturing the same.

In accordance with one aspect of the present invention to achieve the object, there is provided a printed circuit board including: an insulating member having a through via hole; a circuit pattern disposed on the insulating member; a solder resist disposed on the insulating member while exposing a portion of the circuit pattern; a via plating pad connected to the circuit pattern, disposed inside the via hole, and covering a lower opening of the via hole along an inner wall of the via hole; and an external connection means having a center portion coinciding with a center portion of the via hole and disposed on the via plating pad.

Here, the via plating pad disposed in a region corresponding to the lower opening of the via hole, may be formed as a flat surface.

Further, the via plating pad disposed in the region corresponding to the lower opening of the via hole, and a lower surface of the insulating member may be disposed on a straight line.

Further, the printed circuit board may further include a copper foil pattern disposed between the circuit pattern and the insulating member.

Further, the printed circuit board may further include an additional copper foil pattern disposed on the lower surface of the insulating member along a periphery of the lower opening of the via hole, wherein the additional copper foil pattern and the via plating pad disposed in the region corresponding to the lower opening of the via hole may be disposed on a straight line.

Further, the via plating pad disposed in the region corresponding to the lower opening of the via hole may be protruded from the lower surface of the insulating member.

In accordance with another aspect of the present invention to achieve the object, there is provided a method of manufacturing a printed circuit board including: providing first and second base layers each having a through via hole; bonding the first and second base layers with an adhesive member interposed therebetween; forming a via plating pad, which is disposed inside the via hole and covers a lower opening of the via hole along an inner wall of the via hole, and a circuit pattern, which is electrically connected to the via plating pad, on the first and second base layers at the same time; forming a solder resist, which covers the circuit pattern while interposing a portion of the circuit pattern, on the first and second base layers at the same time; forming two printed circuit members by separating the first and second base layers from the adhesive member; and forming an external connection means, which has a center portion coinciding with a center portion of the via hole, on the via plating pad.

Here, the base layer may have a single structure of an insulating member or a dual structure of an insulating member and a copper foil layer.

Further, the via plating pad disposed in a region corresponding to the lower opening of the via hole and a lower surface of the insulating member may be disposed on a straight line.

Further, when the base layer includes a copper foil layer, in forming the circuit pattern, a copper foil pattern is further formed between the circuit pattern and the insulating member.

Further, the base layer may include an insulating member and copper foil layers disposed on both surfaces of the insulating member.

Further, in forming the circuit pattern, a copper foil pattern, which is disposed between the circuit pattern and the insulating member, is further formed by etching the copper foil layer on the insulating member.

Further, after forming the printed circuit member, the method of manufacturing a printed circuit board may further include forming an additional copper foil pattern disposed on the lower surface of the insulating member along a periphery of the lower opening of the via hole by etching the copper foil layer disposed on the lower surface of the insulating member.

Further, the additional copper foil pattern and the via plating pad disposed in the region corresponding to the lower opening of the via hole may be disposed on a straight line.

Further, after forming the printed circuit member, the method of manufacturing a printed circuit board may further include removing the copper foil layer disposed on the lower surface of the insulating member.

Further, the via plating pad disposed in the region corresponding to the lower opening of the via hole may be protruded from the lower surface of the insulating member.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a printed circuit board in accordance with a first embodiment of the present invention;

FIG. 2 is a cross-sectional view of a printed circuit board in accordance with a second embodiment of the present invention;

FIG. 3 is a cross-sectional view of a printed circuit board in accordance with a third embodiment of the present invention;

FIG. 4 is a cross-sectional view of a printed circuit board in accordance with a fourth embodiment of the present invention;

FIGS. 5 to 10 are cross-sectional views for explaining a process of manufacturing a printed circuit board in accordance with a fifth embodiment of the present invention;

FIGS. 11 to 14 are cross-sectional views for explaining a process of manufacturing a printed circuit board in accordance with a sixth embodiment of the present invention;

FIGS. 15 to 18 are cross-sectional views for explaining a process of manufacturing a printed circuit board in accordance with a seventh embodiment of the present invention; and

FIGS. 19 and 20 are cross-sectional views for explaining a process of manufacturing a printed circuit board in accordance with an eighth embodiment of the present invention.

### DETAILED DESCRIPTION OF THE PREFERABLE EMBODIMENTS

Hereinafter, embodiments of the present invention will be described in detail with reference to the accompanying drawings. The following embodiments are provided as examples to fully convey the spirit of the invention to those skilled in the art. Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals throughout the specification.

FIG. 1 is a cross-sectional view of a printed circuit board in accordance with a first embodiment of the present invention.

Referring to FIG. 1, a printed circuit board 100 in accordance with a first embodiment of the present invention may include an insulating member 110 having a through via hole 111, a circuit pattern 120, a solder resist 140, a via plating pad 130, and an external connection means 150.

The insulating member 110 may play roles of giving insulation between interlayer components or between interlayer circuits as well as supporting the printed circuit board 100. For example, the insulating member 110 may include one or two or more of epoxy resin, phenolic resin, polyimide resin, glass fiber impregnated epoxy resin, and FR4 (heat-resistant glass epoxy resin), but the embodiment of the present invention is not limited to the material of the insulating member 110.

The insulating member 110 may include the through via hole 111. Here, the via plating pad 130 is disposed inside the via hole 111 along an inner wall of the through via hole 111 to cover a lower opening of the through via hole 111. At this time, the via plating pad 130 may be electrically connected to the circuit pattern 120 disposed on the insulating member 110.

A region of the via plating pad 130, which corresponds to the lower opening of the via hole 111, may be formed as a flat surface. Here, the region of the via plating pad 130, which corresponds to the lower opening of the via hole 111, and a lower surface of the insulating member 110 may be disposed on a straight line. At this time, since the via plating pad 130 is disposed inside the via hole 111 and a portion thereof is exposed from the insulating member 110, the via plating pad 130 may be electrically isolated from the adjacent via plating pad (here, although one via plating pad is shown in the drawing, the printed circuit board may have substantially a plurality of via plating pads). Accordingly, there is no need to dispose a separate solder resist on the lower surface of the insulating member 110 in order to prevent a short between the adjacent via plating pads 130.

The external connection means 150 has a center potion coinciding with a center portion of the lower opening of the via hole 111 and may be disposed on the via plating pad 130. That is, the via plating pad 130 performs roles of a pad electrode electrically connected to a chip or an external circuit portion as well as an interlayer connection means for electrically conducting upper and lower portions of the insulating member 110. Accordingly, since it is not required to dispose a via and a pad in different regions, it is possible to save a circuit space of the printed circuit board.

For example, the external connection means 150 may be a solder ball, but the embodiment of the present invention is not limited to the type of the external connection means 150.

In addition, the circuit pattern 120 may have a pad 160 for being electrically connected to a chip or an external circuit portion. Further, the solder resist 140 may be further disposed on the insulating member 110 including the circuit pattern 120 to expose the pad 160.

Accordingly, as in the embodiment of the present invention, since the center portion of the via hole coincides with the center portion of the external connection means to save the circuit space, it is possible to reduce an area of the printed circuit board or increase a solder ball mounting region of the printed circuit board.

Further, as the via plating pad in accordance with the embodiment of the present invention is disposed inside the via hole, it is possible to reduce costs as well as processes without the need for a separate solder resist layer.

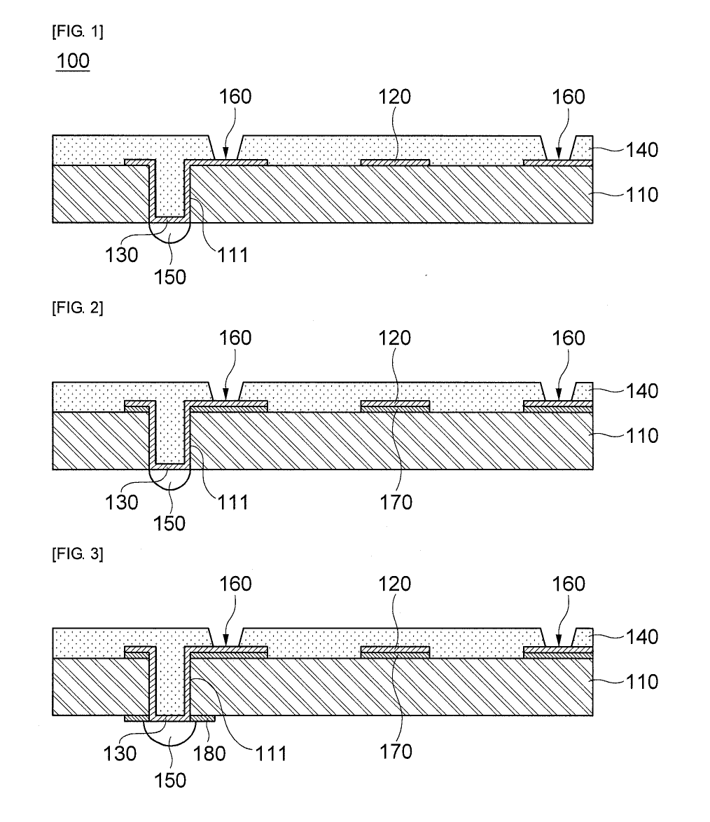

Hereinafter, modified examples of the printed circuit board in accordance with the first embodiment of the present invention will be described with reference to FIGS. 2 to 4.

FIG. 2 is a cross-sectional view of a printed circuit board in accordance with a second embodiment of the present invention.

Here, since a printed circuit board in accordance with a second embodiment has the same technical configuration as the printed circuit board in accordance with the above-described first embodiment except for further disposing a copper foil pattern between an insulating member and a circuit pattern, repeated description will be omitted.

Referring to FIG. 2, a printed circuit board 100 in accordance with a second embodiment of the present invention may include an insulating member 110 having a through via hole 111, a circuit pattern 120 disposed on the insulating member 110, a solder resist 140 disposed on the insulating member 110 while exposing a portion of the circuit pattern 120, a via plating pad 130 disposed inside the via hole 111, connected to the circuit pattern 120, and covering a lower opening of the via hole 111 along an inner wall of the via hole 111, and an external connection means 150 having a center portion coinciding with a center portion of the via hole 111 and disposed on the via plating pad 130.

Here, a copper foil pattern 170 may be further disposed between the insulating member 110 and the circuit pattern 120. The copper foil pattern 170 can improve adhesion between the insulating member 110 and the circuit pattern 120 and play a role of a seed for a plating process for forming the circuit pattern 120.

FIG. 3 is a cross-sectional view of a printed circuit board in accordance with a third embodiment of the present invention.

Here, since a printed circuit board in accordance with a third embodiment has the same technical configuration as the printed circuit board in accordance with the above-described second embodiment except for further disposing an additional copper foil pattern on a lower surface of an insulating member around a via hole, repeated description will be omitted.

Referring to FIG. 3, a printed circuit board 100 in accordance with a third embodiment of the present invention may include an insulating member 110 having a through via hole 111, a circuit pattern 120 disposed on the insulating member 110, a copper foil pattern 170 interposed between the insulating member 110 and the circuit pattern 120, a solder resist 140 disposed on the insulating member 110 while exposing a portion of the circuit pattern 120, a via plating pad 130 connected to the circuit pattern 120 and covering a lower opening of the via hole 111 along an inner wall of the via hole 111, and an external connection means 150 having a center portion coinciding with a center portion of the via hole 111 and disposed on the via plating pad 130.

Here, an additional copper foil pattern 180 may be disposed on a lower surface of the insulating member 110 along a periphery of the via hole 111. That is, the additional copper foil pattern 180 may be disposed around the via plating pad 130. At this time, when the via hole 111 is small, although a solder ball mounting region in the via plating pad 130 may be reduced along with a reduction in area of the via plating pad 130, it is possible to increase the solder ball mounting region by disposing the additional copper foil pattern 180 around the via plating pad 130.

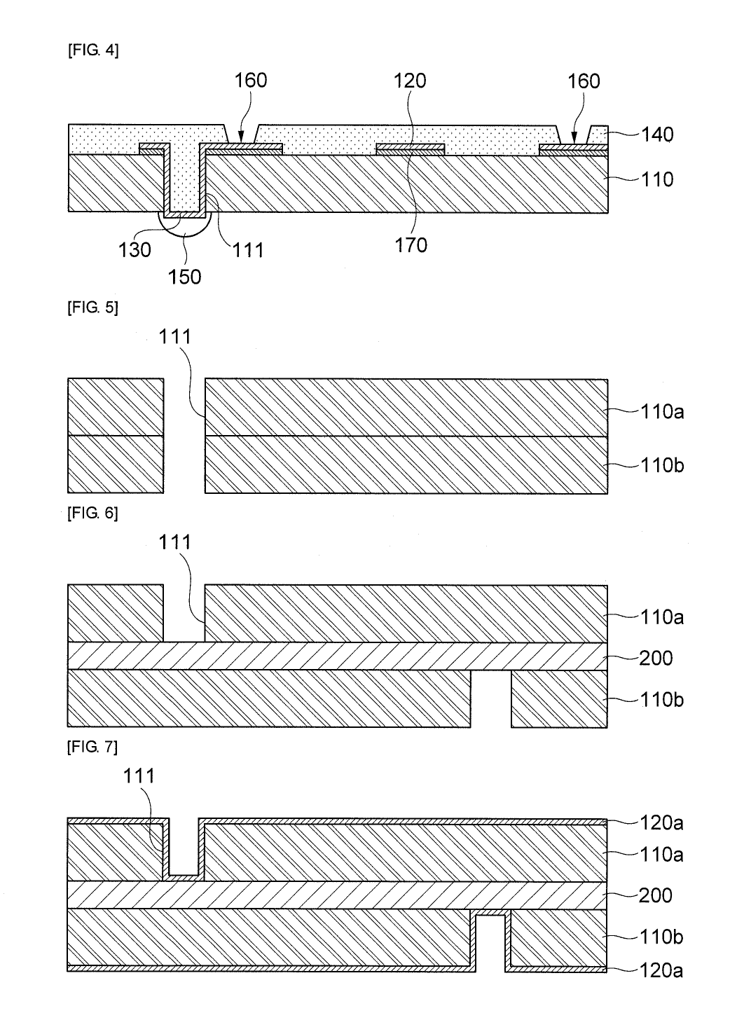

FIG. 4 is a cross-sectional view of a printed circuit board in accordance with a fourth embodiment of the present invention.

Here, since a printed circuit board in accordance with a fourth embodiment has the same technical configuration as the printed circuit board in accordance with the above-described third embodiment except for further not disposing an additional copper foil pattern on a lower surface of an insulating member around a via hole, repeated description will be omitted.

Referring to FIG. 4, a printed circuit board 100 in accordance with a fourth embodiment of the present invention may include an insulating member 110 having a through via hole 111, a circuit pattern 120 disposed on the insulating member 110, a copper foil pattern 170 interposed between the insulating member 110 and the circuit pattern 120, a solder resist 140 disposed on the insulating member 110 while exposing a portion of the circuit pattern 120, a via plating pad 130 connected to the circuit pattern 120 and covering a lower opening of the via hole 111 along an inner wall of the via hole 111, and an external connection means 150 having a center portion coinciding with a center portion of the via hole 111 and disposed on the via plating pad 130.

Here, the via plating pad 130 corresponding to the via hole 111 may protrude from a lower surface of the insulating member 110. At this time, the external connection means 150 may be formed to surround the protruding via plating pad 130. Accordingly, it is possible to increase a contact area between the external connection means 150 and the via plating pad 130, thereby securing electrical connection reliability of the printed circuit board.

Hereinafter, a process of manufacturing a printed circuit board in accordance with an embodiment of the present invention will be described in detail with reference to FIGS. 5 to 19.

FIGS. 5 to 10 are cross-sectional views for explaining a process of manufacturing a printed circuit board in accordance with a fifth embodiment of the present invention.

Referring to FIG. 5, in order to manufacture a printed circuit board in accordance with a fifth embodiment of the present invention, first, first and second base layers 110a and 110b, each of which has a through via hole 111, are provided.

Here, the via holes 111 may be formed in the first and second base layers 110a and 110b at a time after the first and second base layers 110a and 110b are laminated on each other. For example, the via hole 111 may be formed by a method such as laser drilling or mechanical drilling. However, the embodiment of the present invention is not limited to the method of forming the via hole.

Referring to FIG. 6, after forming the first and second base layers 110a and 110b, the first and second base layers 110a and 110b are bonded to each other with an adhesive member 200 interposed therebetween.

Each of the first and second base layers 110a and 110b may consist of an insulating member as a single structure. For example, the insulating member 110 may include one or two or more of epoxy resin, phenolic resin, polyimide resin, glass fiber impregnated epoxy resin, and FR4 (heat-resistant glass epoxy resin), but the embodiment of the present invention is not limited to the material of the insulating member 110.

In the drawing, although the via holes 111, which are formed in the first and second base layers 110a and 110b, are disposed to cross each other, the embodiment of the present invention is not limited to the disposition of the via holes 111. The via holes 111 may be disposed to overlap with each other.

Referring to FIG. 7, metal layers 120a are simultaneously formed on the first and second base layers 110a and 110b bonded by the adhesive member 200. At this time, the metal layers 120a are also formed inside the via holes 110 which are formed in the first and second layers 110a and 110b, respectively.

Here, for example, the metal layer 120a may be formed by an electrolytic copper plating method using a seed layer after forming the seed layer by chemical copper plating. However, the embodiment of the present invention is not limited to the method of forming the metal layer 120a. For example, the metal layer 120a may be formed by a sputtering method, a CVD method, or a printing method.

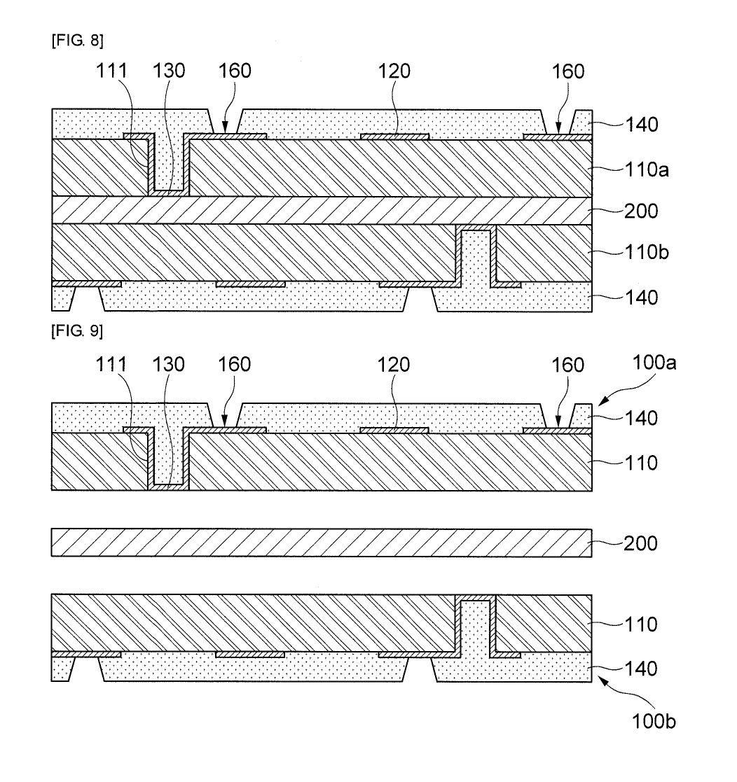

Referring to FIG. 8, a via plating pad 130 and a circuit pattern 120, which is electrically connected to the via plating pad 130, are formed by simultaneously etching the metal layers 120a of the first and second base layers 110a and 110b. Here, the via plating pad 130 may be formed on the adhesive member 200 exposed by the via hole 111 along an inner wall of the via hole 111.

After that, solder resists 140 are simultaneously formed on the first and second base layers 110a and 110b to cover the circuit pattern 120 while exposing a portion of the circuit pattern 120, that is, a pad 160.

Referring to FIG. 9, after forming the circuit pattern 120 and the via plating pad 130, two printed circuit members 100a are formed by separating the first and second base layers 110a and 110b from the adhesive member 200.

Here, the separation of the first and second base layers 110a and 110b from the adhesive member 200 may use physical strength. In addition, when the adhesion between the adhesive member 200 and the first and second base layers 110a and 110b is strong, it is possible to easily separate the first base layer 110a or the second base layer 110b from the adhesive member 200 by physical strength in a heat-treatment state.

Due to removal of the adhesive member 200, the via plating pad 110, which covers a lower opening of the via hole 111, may have a flat surface. Further, the first and second base layers 110a and 110b, that is, a lower surface of the insulating member 110 and a lower surface of the via plating pad 130, which is disposed in a region corresponding to the lower opening of the via hole 111, may be disposed on a straight line. Accordingly, the via plating pad 130 may be disposed inside the via hole 111, and the via plating pad 130 in the region corresponding to the lower opening of the via hole 111 may be exposed to the outside.

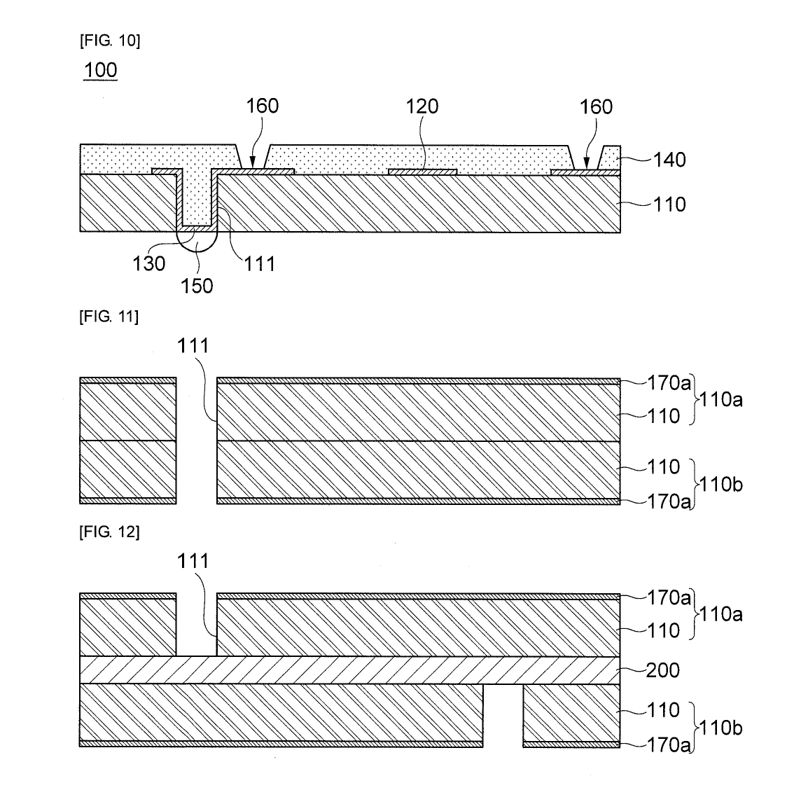

Referring to FIG. 10, after forming the printed circuit member 100a, a printed circuit board 100 is manufactured by forming an external connection member 150 on the via plating pad 130 corresponding to the lower opening of the via hole 111.

The external connection means 150 may be formed by a reflow process after plating a solder paste on the via plating pad 130. For example, the external connection means 150 may be a solder ball. Here, it is possible to save a circuit space of the printed circuit board 100 by forming a center portion of the external connection means 150 to be coincident with a center portion of the via hole 111. At this time, since the adjacent via plating pads 130 are electrically isolated by the insulating member 110, unlike the prior art, it is not required to form a separate solder resist in order to prevent a short between the adjacent via plating pads 130.

Accordingly, the printed circuit board in accordance with the embodiment of the present invention can be manufactured by using the base layer consisting of the insulating member.

FIGS. 11 to 14 are cross-sectional views for explaining a process of manufacturing a printed circuit board in accordance with a sixth embodiment of the present invention. Here, since a sixth embodiment uses the same manufacturing process as the above-described fifth embodiment except for a material of a base layer, repeated description will be omitted.

Referring to FIG. 11, in order to manufacture a printed circuit board in accordance with a sixth embodiment of the present invention, first, first and second base layers 110a and 110b, each of which has a through via hole 111, are provided.

Here, each of the first and second base layers 110a and 110b may include an insulating member 110 and a copper foil layer 170a disposed on one surface of the insulating member 110.

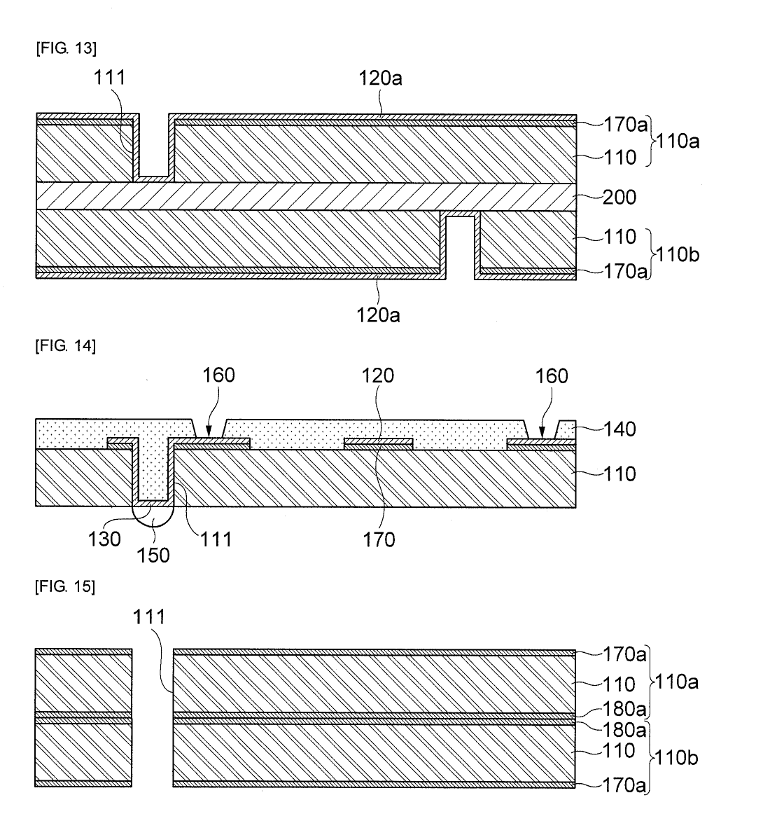

Referring to FIG. 12, after bonding the first and second base layers 110a and 110b by an adhesive member 200, as in FIG. 13, metal layers 120a are formed on the first and second base layers 110a and 110b. At this time, the metal layers 120a also may be formed inside the via holes 111.

Referring to FIG. 14, after forming the metal layer 120a, a circuit pattern 120 and a via plating pad 130, which is disposed inside the via hole 111 to be electrically connected to the circuit pattern 120, are formed by etching the metal layer 120a. Here, a copper foil pattern 170, which is disposed between the circuit pattern 120 and the insulating member 110, may be formed by etching the copper foil layer 170a as well in the process of forming the circuit pattern 120.

After that, after forming a solder resist 140 to cover the circuit pattern 120, the first and second base layers 110a and 110b are separated from the adhesive member 200 so that it is possible to form two printed circuit members 100a at the same time by once process.

After that, a printed circuit board is manufactured by forming an external connection means 150 on the via plating pad 130 in such a way that a center portion of the via hole coincides with a center portion of the external connection means 150.

Accordingly, the printed circuit board in accordance with the embodiment of the present invention can be manufactured by using the base layer having the copper foil layer on at least one surface.

FIGS. 15 to 17 are cross-sectional views for explaining a process of manufacturing a printed circuit board in accordance with a seventh embodiment of the present invention. Here, since a seventh embodiment uses the same manufacturing process as the above-described sixth embodiment except for a material of a base layer, repeated description will be omitted.

Referring to FIG. 15, in order to manufacture a printed circuit board in accordance with a seventh embodiment of the present invention, first, first and second base layers 110a and 110b, each of which has a through via hole 111, are provided.

Here, each of the first and second base layers 110a and 110b may include an insulating member 110 and copper foil layers 170a and 180a disposed on both surfaces of the insulating member 110. For example, the first and second base layers 110a and 110b may be copper clad laminates (CCLs).

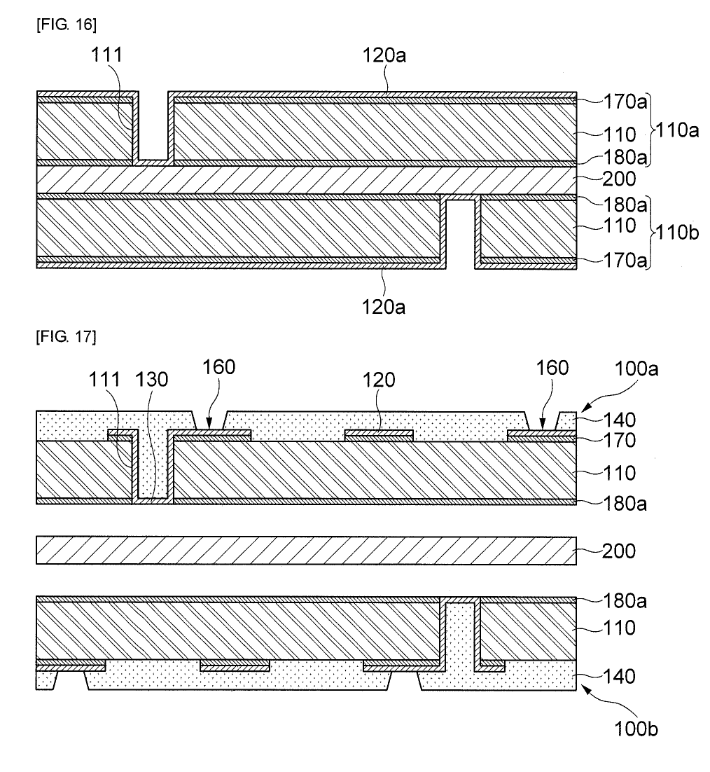

Referring to FIG. 16, the first and second base layers 110a and 110b are bonded by an adhesive member 200. After that, metal layers 120a are formed on the first and second base layers 110a and 110b. At this time, the metal layers 120a may be formed inside the via holes 111.

Referring to FIG. 17, a circuit pattern 120 and a via plating pad 130, which is electrically connected to the circuit pattern 120, are simultaneously formed on the first and second base layers 110a and 110b by etching the metal layer 120a.

Here, in the process of forming the circuit pattern 120, a copper foil pattern 170 may be formed between the insulating member 110 and the circuit pattern 120 by etching the copper foil layer 170a disposed on an upper surface of the insulating member 110 as well.

After that, two printed circuit members 100a are formed by separating the first and second base layers 110a and 110b from the adhesive member 200. At this time, since the copper foil layers 180a are disposed on lower surfaces of the first and second base layers 110a and 110b, the first and second base layers 110a and 110b are easily separated from the adhesive member 200.

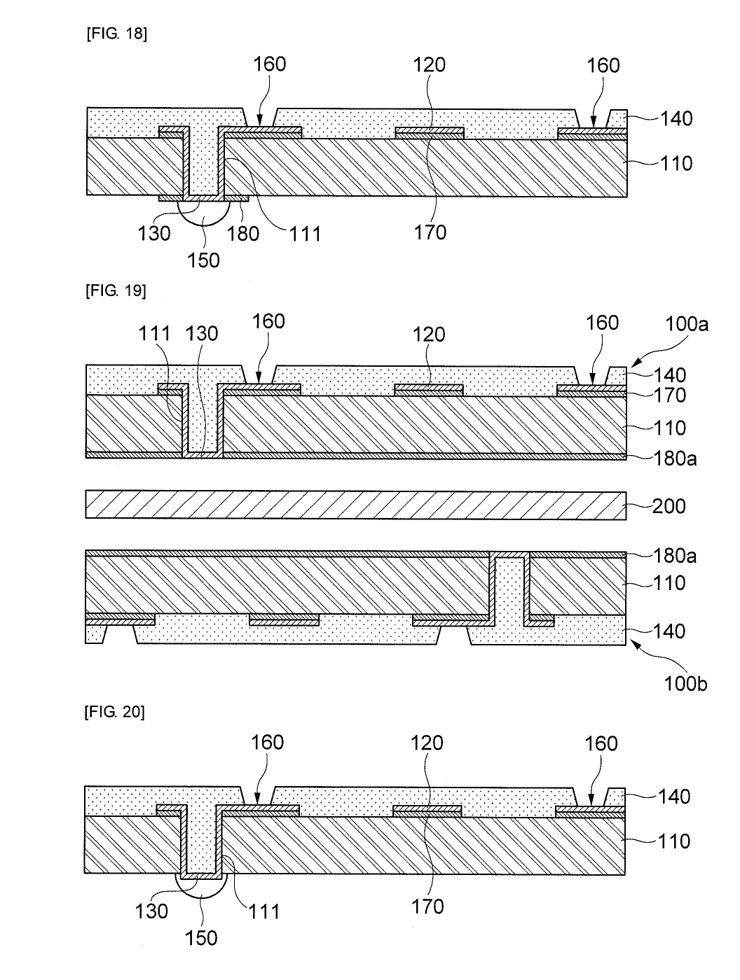

Referring to FIG. 18, an additional copper foil pattern 180 is further formed around the via hole 111 by etching the copper foil layer 180a disposed on the lower surface of the insulating member 110. Here, the additional copper foil pattern 180 and a lower surface of the via plating pad 130, which corresponds to a lower opening of the via hole 111, may be disposed on a straight line. At this time, the additional copper foil pattern 180 may be disposed around the via plating pad 130, which covers the lower opening of the via hole 111, to increase a solder ball mounting region.

After that, a printed circuit board is manufactured by forming an external connection means 150 on the via plating pad 130. At this time, although the via plating pad 130 has a small size due to a small size of the via hole 111, a region for forming the external connection means 150 may be increased by the additional copper foil pattern 180 disposed around the via plating pad 130.

Accordingly, the printed circuit board in accordance with the embodiment of the present invention can be manufactured by using the base layer having the copper foil layers on the both surfaces.

FIGS. 19 and 20 are cross-sectional views for explaining a process of manufacturing a printed circuit board in accordance with an eighth embodiment of the present invention. Here, since an eighth embodiment uses the same manufacturing process as the above-described seventh embodiment, repeated description will be omitted.

Referring to FIG. 19, in order to manufacture a printed circuit board in accordance with an eighth embodiment of the present invention, a circuit pattern 120 and a via plating pad 130, which is electrically connected to the circuit pattern 120, are simultaneously formed on each of the first and second base layers 110a and 110b bonded by an adhesive member 200.

After that, two printed circuit members 100a are formed by separating the first and second base layers 110a and 110b from the adhesive member 200.

Referring to FIG. 20, a copper foil layer 180a disposed on a lower surface of the printed circuit member 100a is removed. Accordingly, the via plating pad 130 disposed inside a via hole 111 may protrude from a lower surface of an insulating member 110.

After that, an external connection means 150 is formed on the via plating pad 130. At this time, the external connection means 150 may be formed to cover the via plating pad 130 protruding from the insulating member 110. Therefore, it is possible to increase a contact area between the external connection means 150 and the via plating pad 130, thereby improving contact reliability of the external connection means 150.

Therefore, as in the embodiments of the present invention, since the two printed circuit boards having the via plating pads can be manufactured by once process, it is possible to manufacture a printed circuit board capable of implementing fine pitch and miniaturization by saving a circuit space as well as reducing process costs.

Further, since it is not required to form a separate solder resist on the lower surface of the insulating member on which the external connection means is formed, it is possible to reduce process costs as well as simplifying processes.

Since the printed circuit board of the present invention includes the external connection means disposed inside the via hole, having the center portion coinciding with the center portion of the lower opening of the via hole, and disposed on the via plating pad, it is possible to save a circuit space, thereby reducing an area of a printed circuit board or implementing fine pitch of a solder ball.

Further, since the printed circuit board of the present invention can form the via plating pad to be protruded from the insulating member, it is possible to improve contact reliability of a solder ball.

Further, since the printed circuit board of the present invention disposes the via plating pad inside the via hole, it is possible to simplify processes and reduce process costs without the need for a separate solder resist.

Further, since the process of manufacturing a printed circuit board of the present invention can manufacture two printed circuit boards by once process, it is possible to reduce process costs.

What is claimed is:

1. A printed circuit board comprising:
an insulating member having a through via hole;
a circuit pattern disposed on the insulating member;
a solder resist disposed on the insulating member while exposing a portion of the circuit pattern;
a via plating pad connected to the circuit pattern, disposed inside the via hole, and covering a lower opening of the via hole along an inner wall of the via hole; and
an external connection means having a center portion coinciding with a center portion of the via hole and disposed on the via plating pad.

2. The printed circuit board according to claim 1, wherein the via plating pad disposed in a region corresponding to the lower opening of the via hole is formed as a flat surface.

3. The printed circuit board according to claim 1, wherein the via plating pad disposed in the region corresponding to the lower opening of the via hole and a lower surface of the insulating member are disposed on a straight line.

4. The printed circuit board according to claim 1, further comprising:
a copper foil pattern disposed between the circuit pattern and the insulating member.

5. The printed circuit board according to claim 4, further comprising:
an additional copper foil pattern disposed on the lower surface of the insulating member along a periphery of the lower opening of the via hole, wherein the additional copper foil pattern and the via plating pad disposed in the region corresponding to the lower opening of the via hole are disposed on a straight line.

6. The printed circuit board according to claim 1, wherein the via plating pad disposed in the region corresponding to the lower opening of the via hole is protruded from the lower surface of the insulating member.

7. A method of manufacturing a printed circuit board comprising:
providing first and second base layers each having a through via hole;
bonding the first and second base layers with an adhesive member interposed therebetween;
foming a via plating pad, which is disposed inside the via hole and covers a lower opening of the via hole along an inner wall of the via hole, and a circuit pattern, which is electrically connected to the via plating pad, on the first and second base layers at the same time;
forming a solder resist, which covers the circuit pattern while exposing a portion of the circuit pattern, on the first and second base layers at the same time;
forming two printed circuit members by separating the first and second base layers from the adhesive member; and
forming an external connection means, which has a center portion coinciding with a center portion of the via hole, on the via plating pad.

8. The method of manufacturing a printed circuit board according to claim 7, wherein the base layer has a single structure of an insulating member or a dual structure of an insulating member and a copper foil layer.

9. The method of manufacturing a printed circuit board according to claim 8, wherein the via plating pad disposed in a region corresponding to the lower opening of the via hole and a lower surface of the insulating member are disposed on a straight line.

10. The method of manufacturing a printed circuit board according to claim 8, wherein in forming the circuit pattern, a copper foil pattern is further formed between the circuit pattern and the insulating member when the base layer comprises a copper foil layer.

11. The method of manufacturing a printed circuit board according to claim 7, wherein the base layer comprises an insulating member and copper foil layers disposed on both surfaces of the insulating member.

12. The method of manufacturing a printed circuit board according to claim 11, wherein in forming the circuit pattern, a copper foil pattern, which is disposed between the circuit pattern and the insulating member, is further formed by etching the copper foil layer on the insulating member.

13. The method of manufacturing a printed circuit board according to claim 12, further comprising, after forming the printed circuit members,
forming an additional copper foil pattern disposed on the lower surface of the insulating member along a periphery of the lower opening of the via hole by etching the copper foil layer disposed on the lower surface of the insulating member.

14. The method of manufacturing a printed circuit board according to claim 13, wherein the additional copper foil pattern and the via plating pad disposed in the region corresponding to the lower opening of the via hole are disposed on a straight line.

15. The method of manufacturing a printed circuit board according to claim 11, further comprising, after forming the printed circuit members,
removing the copper foil layer disposed on the lower surface of the insulating member.

16. The method of manufacturing a printed circuit board according to claim 15, wherein the via plating pad disposed in the region corresponding to the lower opening of the via hole is protruded from the lower surface of the insulating member.
